(19) United States
(12) Patent Application Publication
(10) Pub. No.: US 2004/0024549 A1
(43) Pub. Date: Feb. 5, 2004

(54) Remote counting device for a printing system

(75) Inventors: Alistair Egan, Oxnard, CA (US); Yuen W. Wong, Agoura, CA (US); Elizabeth Fitzgerald, Woodland Hills, CA (US)

Correspondence Address: Mr. Eric S. Chen, PILLSBURY MADISON & SUTRO LLP, Suite 2800, 725 South Figueroa Street, Los Angeles, CA, 90017, US

(73) Assignee: HITACHI KOKI IMAGING SOLUTIONS, INC.

(21) Appl. No.: 10/080,694

(22) Filed: Feb. 22, 2002

(51) Int. Cl. G06F 19/00; G01R 25/00; G01R 29/02

(52) U.S. Cl. 702/79

(57) ABSTRACT

A method of storing and outputting a count for an imaging device. The method includes storing the count in a memory storage device. A continuous active signal is detected from an input, the input including continuous active signals and continuous steady-state signals. Also, a count request is receivable from a remote device. The count in the memory storage device is incremented when the continuous active signal from the input is detected. Finally, the count is outputting to the remote device.

### BACKGROUND OF THE INVENTION

1. Field of the Invention

The present invention relates generally to the art of monitoring paper scanners, copiers or media processors, and more particularly, to a system, method, and apparatus for remotely retrieving a count of pages printed on at least one imaging device.

2. Discussion of the Related Art

Photocopier monitoring systems are known in the art. There are monitoring systems for imaging devices that utilize a counter to count the number of pages processed by an imaging device such as a scanner or photocopier, and provide an electrical count signal for each paper printed. The electrical count signal may be a simple electrical pulse, which may be, in its most elemental form, a sustained high-voltage level signal for a predetermined time period. In such systems, the electric count signal is sent from the photocopier to a counter device. Such systems test the electric count signal to ensure it is authentic, and not simply the product of electrical noise. Such systems start an internal clock when a high-voltage level of an electric pulse signal is detected, and, if the electric pulse signal is still high at the end of a preset clock period, the system assumes that the electric count signal is valid. However, such systems use up much of a CPU's processing capacity, because a portion of the CPU is dedicated to testing the signal at preset intervals during the preset time period. As a result, if the CPU is executing other functions while testing the signal, those functions are processed more slowly.

Many of the current page counter systems in the art have the capability to send a page count from the counter to a remote facility at periodic intervals. However, such systems only send page counts at predetermined intervals. Therefore, it is desirable to request the count data at different times, and/or on demand.

Accordingly, it is desirable to provide a system for monitoring an imaging machine that overcomes the shortcomings of the systems described above.

### BRIEF DESCRIPTION OF THE DRAWINGS

FIG. 1 illustrates an overview of a remotely accessible counter device according to an embodiment of the present invention;

FIG. 2A illustrates one embodiment of the signal authentication process that occurs when a high voltage is detected by the counter device according to an embodiment of the present;

FIG. 2B illustrates a second embodiment of the signal authentication process that occurs when a high voltage is detected by the counter device according to an embodiment of the present invention; and

FIG. 3 illustrates a flowchart showing the processing that occurs from when a remote device requests a count, until the count is transferred to the remote device according to an embodiment of the present invention.

### DETAILED DESCRIPTION

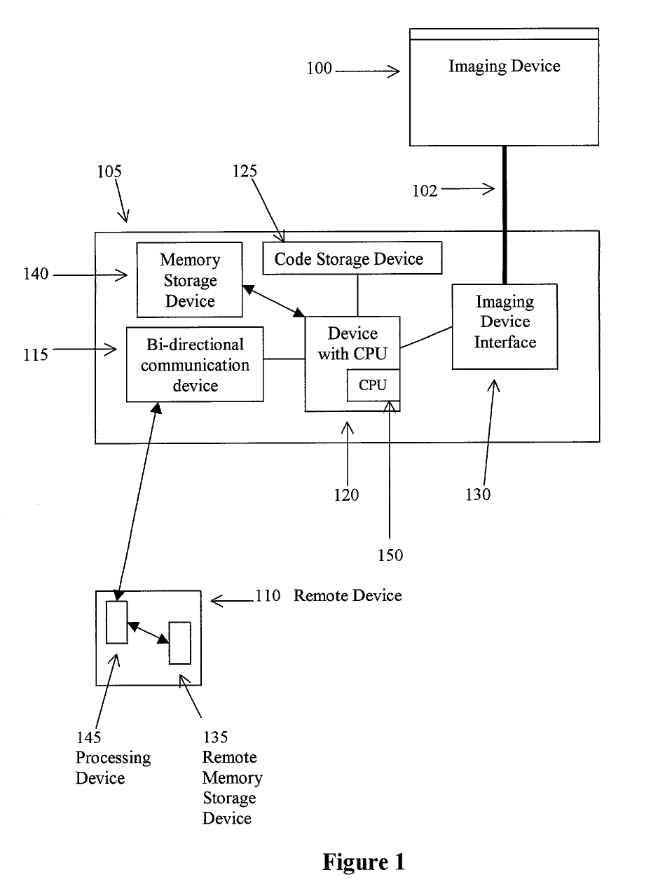

The present invention is a remotely accessible counter device for counting, for example, pages scanned or printed on an imaging sy ste m such as a copier, computer printer, or scanner. FIG. 1 illustrates an overview of a remotely accessible counter device according to an embodiment of the present invention. In the preferred embodiment, a remote device 110 may remotely access a counter device 105 that counts pages printed or scanned on an imaging device or system 100.

The imaging device 100 may be a copier, scanner, or a group of copiers or scanners, for example. When the imaging device 100 prints a copy or scans an image, an electrical signal is sent to a imaging device interface 130 at the counter device 105. This electrical signal may be communicated over a wire 102, or other suitable connection. The wire 102 is used to facilitate communication between the imaging device 100 and the counter device 105. Imaging devices often contain a control section that creates and outputs a signal when a copy is printed or a page is scanned. This signal may be an electrical signal. In imaging devices, a constant (“steadystate”) voltage signal is outputted while the imaging device 100 is turned on. When a copy is printed or a page is scanned, a constant signal of a voltage different than the steady state voltage level is produced for a certain period of time. This non-steady-state signal is known as an “active signal.”

In many imaging devices 100, the steady-state voltage has a low-voltage level. When a copy is printed or a page is scanned, a higher voltage level is produced for a certain length of time that is dependent upon the brand and type of imaging device 100, as well as the size of the media copied or printed. The active signal is sent from the imaging device 100 to the imaging device interface 130 via the wire 102. A device with a CPU 120 receives the active signal from the imaging device interface 130. A CPU 150, or any other processor, contained within the device with a CPU 120 then tests the active signal to ensure that it is authentic, and not simply the product of electrical noise on the wire 102. A code storage device 125 holds the program code that the CPU 150 executes when authenticating an active signal. The code storage device 125 may be a ROM, EPROM, or any other device capable of storing processor code. A memory storage device 140 is utilized to store a count of the number of copies printed or pages scanned by the imaging device 100. If the CPU 150 determines that an active signal is authentic, the count stored in the memory storage device 140 is incremented.

A remote device 110 at a remote location may obtain a count from the counter device 105. When a count is desired, a user may utilize the remote device 110 to send a count request signal to a bi-directional communication device 115, such as a pager, in the counter device 105. The CPU 150 receives the request from the bi-directional communication device pager 115. The CPU 150 then accesses the electrical counter 140 and reads the count. The program code used by the CPU 150 to access the memory storage device 140 is preferably stored within the code storage device 125.

The remote device 110 has its own remote memory storage device 135 in which a count total received from the counter device 105 is stored. Every time the remote device 110 receives a count from the counter device 105, a processing device 145 at the remote device 110 takes the count and subtracts the number stored in the remote memory storage device 135. The resultant number is then made accessible to a user. The count from the counter device 105 is then stored in the remote memory storage device 135. This way, a user can access a count of pages copied or scanned by the imaging device 100, and know how many pages have been copied or scanned since the last time the count was checked. The remote memory storage device 135 may be located within the remote device 110, for example.

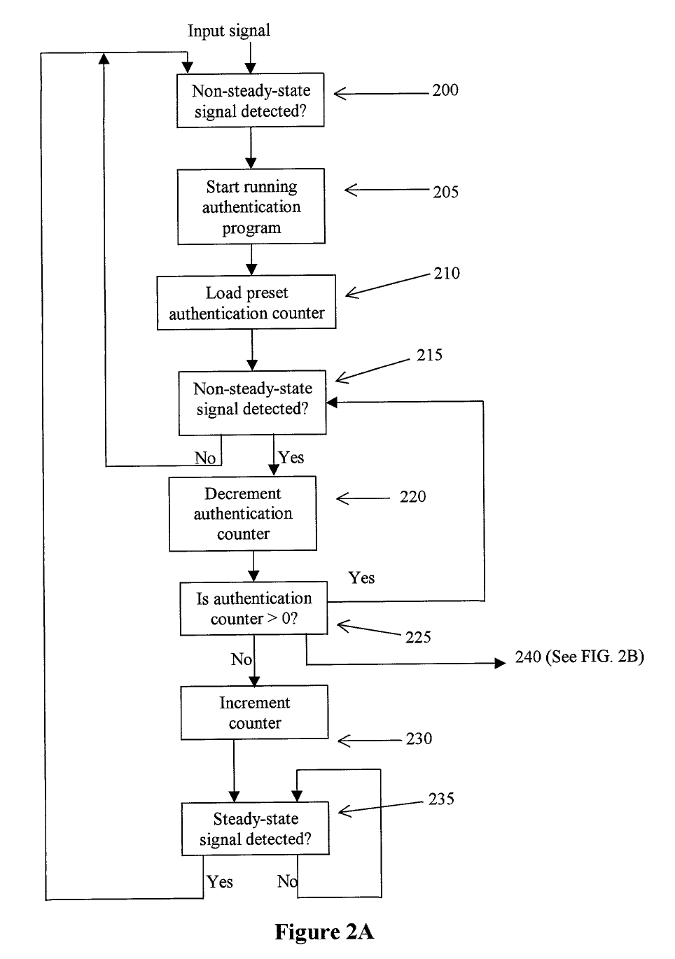

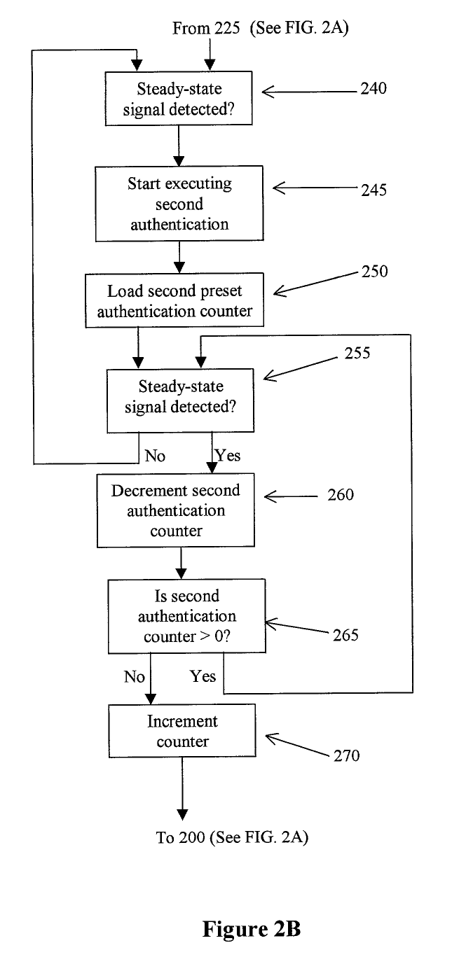

FIG. 2A illustrates one embodiment of the signal authentication process that occurs when an active signal is detected by the counter device 105 according to an embodiment of the present invention. When an active signal is detected 200 by the CPU 150, the CPU 150 starts executing 205 an authentication program or subroutine. Next, an authentication counter is loaded 210 with a preset value of t−1. From start to finish, the active signal is tested t times (t−1 is loaded in the authentication counter because once the authentication counter is set, one non-steady-state voltage level has to have already been detected) to determine whether the active signal is authentic, since all authentic active signals have a non-steady-state voltage level for at least a minimum amount of time, the time varying depending upon the type and brand of the imaging device 100, as well as the size and type of document that is operated on by the imaging device 100. The greater the speed and processing capacity of the CPU 150, the more times each active signal may need to be tested.

The program then executes a loop during which the active signal is checked for t−1 times. If the active signal is determined to have a non-steady-state voltage level for each of these times, then the active signal is considered authentic. This test program is not clock-dependant. In other words, the t−1 tests do not necessarily have to always occur within the same time period for the testing of each pulse. The number of tests is determined based upon a known minimum length of a pulse signal as well as the CPU 150 speed and processing capacity.

If a high voltage level is detected 215, the authentication counter is decremented 220. Next, if the authentication counter is greater 225 than zero, the program once again checks 215 for a high voltage. This iteration continues until the authentication counter reaches zero. At this point, in one embodiment, the program determines that the active signal is authentic, and the CPU 150 increments 230 the count stored in the memory storage device 140. In this embodiment, the program then waits for the next low voltage level before testing for the next pulse. The program continually tests 235 for a steady-state voltage signal. When a steady-state signal is detected, the system then waits until the next non-steady-state signal is detected 200.

FIG. 2B illustrates a second embodiment of the signal authentication process that occurs when a high voltage is detected by the counter device according to an embodiment of the present invention. In this embodiment, after an active signal has been verified 225 as being non-steady-state for the predetermined number of times, the system waits until a continuous steady-state voltage is received for a period of time, thereby ensuring that the detected active signal really is authentic, and not merely the product of electrical noise. In such an embodiment, after the CPU 150 has verified 225 that a signal was active for the set number of times, the CPU 150 waits until a steady-state voltage signal is detected 240, and begins executing 245 a second authentication program, or a second authentication subroutine in the aforementioned authentication program. A second preset authentication counter is loaded 250 with a preset value of r−1. From start to finish, a steady-state signal is tested r times (r−1 is loaded in the authentication counter because once the authentication counter is set, one steady-state voltage level has to have already been detected) to determine whether the steady-state signal is authentic. If a steady-state voltage level is detected 255, the second authentication counter is decremented 260. Next, if the second authentication counter is greater 265 than zero, the program once again checks 255 for a steady-state voltage level. This iteration continues until the second authentication counter reaches zero. At this point, the program determines that an authentic active signal was followed by an authentic steady-state signal, the CPU 150 increments 270 the count stored in the memory storage device 140. The system then waits to detect 200 the next non-steady-state signal.

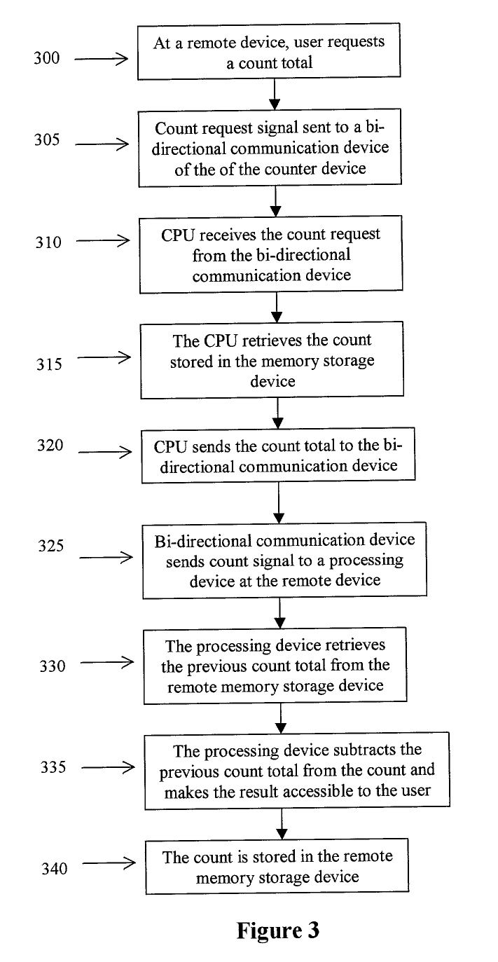

FIG. 3 illustrates a flowchart showing the processing that occurs from when the remote device 110 requests a count, until the count is transferred to the remote device 110 according to an embodiment of the present invention. First, a user at the remote device 110 may request 300 a count total. Second, the remote device 110 sends 305 a count request signal to the bi-directional communication device 115 of the counter device 105. The CPU 150 then receives 310 the count request from the bi-directional communication device 115. Next, the CPU 150 retrieves 315 the count stored in the memory storage device 140. The CPU 150 sends 320 the count total to the bi-directional communication device 115. The bi-directional communication device 115 sends 325 a signal containing the count to a processing device 145 at the remote device 110. The processing device 145 retrieves 330 the previous count total from the remote memory storage device 135. The processing device 145 then subtracts the previous count total from the count and makes 335 the result accessible to the user. Finally, the count is stored 340 in the remote memory storage device 135.

While the description above refers to particular embodiments of the present invention, it will be understood that many modifications may be made without departing from the spirit thereof The accompanying claims are intended to cover such modifications as would fall within the true scope and spirit of the present invention. The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. An electrical pulse detection system for an imaging system, comprising:
an electrical signal-receiving device to receive an electrical signal, wherein the electrical signal includes a continuous steady-state signal and a continuous active signal, the steady-state signal and the active signal having different voltage levels;
a code-storage device to store program code;
a memory storage device to store a number representing a count of the active signals received by the electrical signal-receiving device; and
a processor to access and execute the program code, wherein the program code is adapted to detect the active signal of the electrical signal received by the electrical pulse-receiving device, wherein execution of the program code causes the processor to execute a subroutine when the active signal is detected, the subroutine testing the detected active signal for up to a set number of times, and when the active signal is detected for each of the set number of times during execution of the subroutine, the number stored in the memory device is incremented.

2. The system of claim 1, wherein the code-storage device is a read-only memory (ROM).

3. The system of claim 1, wherein the imaging system is a scanning system.

4. The system of claim 1, wherein the imaging system is a printing system

5. The system of claim 4, wherein the printing system is at least one copier.

6. The system of claim 4, wherein the printing system is at least one computer printer.

7. An electrical pulse detection system for an imaging system, comprising:
an electrical signal-receiving device to receive an electrical signal, wherein the electrical signal includes a continuous steady-state signal and a continuous active signal, the steady-state signal and the active signal having difference voltage levels;
a code-storage device to store program code;
a memory storage device to store a number representing a count of the active voltage levels received by the electrical signal-receiving device; and
a processor to access and execute the program code, wherein the program code is adapted to detect the active signal of the electrical signal received by the electrical signal-receiving device, wherein execution of the program code causes the processor to execute a subroutine when the active signal is detected, the subroutine testing the detected active signal for up to a set number of times, and when the active signal is detected for each of the set number of times during execution of the subroutine, the processor tests a subsequently detected steady-state signal for up to a second set number of times, and when the steady-state signal is detected for each of the second set number of times, the number stored in the memory storage device is incremented.

8. The system of claim 7, wherein the code-storage device is a read-only memory (ROM).

9. The system of claim 7, wherein the imaging system is a scanning system.

10. The system of claim 7, wherein the imaging system is a printing system.

11. The system of claim 10, wherein the printing system is at least one copier.

12. The system of claim 10, wherein the printing system is at least one computer printer.

13. A method of storing and outputting a count for an imaging device, comprising:
storing the count in a memory storage device;
detecting a continuous active signal from an input, wherein the input includes continuous active signals and continuous steady-state signals;
receiving a count request from a remote device;
incrementing the count in the memory storage device when the continuous active signal from the input is detected; and
outputting the count to the remote device.

14. The method of claim 13, wherein detecting the continuous active signal includes testing the active signal for up to a set number of times.

15. The method of claim 14, wherein detecting the continuous active signal further includes testing a subsequent steady-state signal for up to a second set number of times.

16. The method of claim 13, wherein the continuous active signal represents a signal from the imaging device indicating that an imaging job has been completed.

17. The method of claim 13, wherein the count is accessible to a computer system.

18. The method of claim 13, wherein the code-storage device is a read-only memory (ROM).

19. The system of claim 13, wherein the imaging system is a scanning system.

20. The system of claim 13, wherein the imaging system is a printing system.

21. The system of claim 20, wherein the printing system is at least one copier.

22. The system of claim 20, wherein the printing system is at least one computer printer.
